(19) United States
(12) Patent Application Publication
(10) Pub. No.: US 2023/0329026 A1
(43) Pub. Date: Oct. 12, 2023

(54) QUANTUM DOT, METHOD OF MANUFACTURING QUANTUM DOT, OPTICAL MEMBER INCLUDING QUANTUM DOT, AND ELECTRONIC APPARATUS INCLUDING QUANTUM DOT

(71) Applicant: Samsung Display Co., Ltd., Yongin-si (KR)

(72) Inventors: Seungwon Park, Yongin-si (KR); Kawon Pak, Yongin-si (KR); Seunghee Jang, Yongin-si (KR); Donghee Lee, Yongin-si (KR); Taekjoon Lee, Yongin-si (KR); Junehyuk Jung, Yongin-si (KR)

(21) Appl. No.: 18/133,383

(22) Filed: Apr. 11, 2023

(30) Foreign Application Priority Data
Apr. 12, 2022 (KR) 10-2022-0045263

(51) Int. Cl. H10K 50/115; B82Y 30/00; B82Y 40/00; C09K 11/70

(52) U.S. Cl. CPC H10K 50/115; C09K 11/70; B82Y 40/00; B82Y 30/00

(57) ABSTRACT

An electronic apparatus including the quantum dot, wherein the quantum dot may include a core and a shell covering at least a portion of the core, wherein the core may include indium (In), gallium (Ga), and phosphorus (P), the shell may include a group II-VI semiconductor compound, a group III-V semiconductor compound, a group III-VI semiconductor compound, or a combination thereof, in the core and the shell, the number of moles of Ga relative to the sum of the number of moles of In and the number of moles of Ga (M^{Ga}/(M^{In}+M^{Ga})) may be in a range of about 0.02 to about 0.18, and in the core and the shell, the sum of the number of moles of In and the number of moles of Ga relative to the number of moles of P ((M^{In}+M^{Ga})/M^{P}) may be in a range of about 1 to about 1.2.

### CROSS-REFERENCE TO RELATED APPLICATION

This application claims priority to and the benefit of Korean Patent Application No. 10-2022-0045263, filed on Apr. 12, 2022, in the Korean Intellectual Property Office, the disclosure of which is incorporated by reference herein in its entirety.

### BACKGROUND

### 1. Field

One or more embodiments relate to a quantum dot, a method of manufacturing the quantum dot, an optical member including the quantum dot, and/or an electronic apparatus including the quantum dot.

### 2. Description of the Related Art

Quantum dots may be used as materials that perform one or more suitable optical functions (for example, a light conversion function, a light emission function, and/or the like) in optical members and one or more suitable electronic apparatuses. Quantum dots, which are semiconductor nanocrystals with a quantum confinement effect, may have different energy bandgaps by control of the size and composition of the nanocrystals, and thus may emit light of one or more suitable emission wavelengths.

An optical member including such quantum dots may have the form of a thin film, for example, a thin film patterned for each sub-pixel. Such an optical member may be used as a color conversion member of a device including one or more suitable light sources.

Quantum dots may be used for a variety of purposes in one or more suitable electronic apparatuses. For example, quantum dots may be used as emitters. For example, quantum dots may be included in an emission layer of a light-emitting device including a pair of electrodes and the emission layer, and may serve as an emitter.

Currently, to implement high-definition optical members and electronic apparatuses, there is a need for the development of quantum dots that emit blue light having a maximum emission wavelength of 490 nm or less, have high photoluminescence quantum yield (PLQY), and/or do not include cadmium that may be a toxic element (e.g., do not include any cadmium).

### SUMMARY

Aspects of one or more embodiments are directed toward a quantum dot having excellent or suitable absorbance and excellent or suitable quantum yield, a method of manufacturing the quantum dot, which may prevent or reduce loss of gallium (Ga) in forming a shell in a core, an optical member including the quantum dot, and/or an electronic apparatus including the quantum dot.

Additional aspects will be set forth in part in the description which follows and, in part, will be apparent from the description, or may be learned by practice of the presented embodiments of the disclosure.

According to one or more embodiments,

a quantum dot may include a core and a shell around (e.g., covering) at least a portion of the core,

wherein the core may include indium (In), gallium (Ga), and phosphorus (P),

the shell may include a group II-VI semiconductor compound, a group III-V semiconductor compound, a group III-VI semiconductor compound, or any combination thereof,

the number of moles of Ga relative to the sum of the number of moles of In and the number of moles of Ga (M^{Ga}/(M^{In}+M^{Ga})) in the core and the shell may be in a range of about 0.02 to about 0.18, and

the sum of the number of moles of In and the number of moles of Ga relative to the number of moles of P ((M^{In}+M^{Ga})/M^{P}) in the core and the shell may be in a range of about 1 to about 1.2.

According to one or more embodiments,

a method of manufacturing a quantum dot may include preparing a first composition including a precursor including indium (In), a precursor including gallium (Ga), a precursor including zinc (Zn), a fatty acid, and a solvent,

preparing a second composition including a precursor including phosphorus (P),

preparing a first mixture by mixing the first composition with the second composition,

manufacturing a core by heating the first mixture, and

manufacturing a shell covering at least a portion of the core,

wherein the core manufactured by the manufacturing of the core may include indium (In), gallium (Ga), and phosphorus (P),

the sum of the number of moles of In and the number of moles of Ga relative to the number of moles of P ((M^{In}+M^{Ga})/M^{P}) in the core may be in a range of about 1 to about 1.5.

According to one or more embodiments, an optical member may include the quantum dot.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 shows a schematic cross-sectional view of a quantum dot according to an embodiment;

FIG. 2 shows a graph illustrating a peak to valley ratio and a half width half maximum (HWHM) of a UV-Vis spectrum of a core according to an embodiment;

FIG. 3 is a schematic cross-sectional view of an electronic apparatus according to an embodiment;

FIG. 4 is a schematic cross-sectional view of an electronic apparatus according to another embodiment; and

FIG. 5 shows a graph illustrating UV-Vis spectra of cores according to Example 1-1 and Comparative Examples 1-1 to 1-4;

FIG. 6A shows a graph illustrating UV-Vis spectra of cores according to Examples 1-1 to 1-3 and Comparative Example 1-1;

FIG. 6B shows a graph illustrating UV-Vis spectra of cores according to Examples 2-1 to 2-5;

FIG. 6C shows a graph illustrating UV-Vis spectra of cores according to Examples 3-1 to 3-5;

FIG. 7 shows a graph illustrating a quantum yield of a quantum dot according to HWHM of cores of quantum dots according to Examples 4-1 to 4-9;

FIG. 8A shows a UV-Vis spectrum and photoluminescence (PL) spectrum of a quantum dot according to Example 6; and

FIG. 8B shows a high-angle annular dark field (HADDF) TEM (e.g., HAADF-STEM) image of the quantum dot according to Example 6.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described, by referring to the drawings, to explain aspects of the present description. As used herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

As the disclosure allows for one or more suitable changes and numerous embodiments, particular embodiments will be illustrated in the drawings and described in more detail in the written description. Effects, features, and a method of achieving the disclosure will be obvious by referring to example embodiments of the disclosure with reference to the attached drawings. The disclosure may, however, be embodied in many different forms and should not be construed as being limited to the embodiments set forth herein.

It will be understood that, although the terms first, second, etc. may be used herein to describe one or more suitable elements, these elements should not be limited by these terms. These terms are only used to distinguish one element from another.

In the embodiments described in the present specification, an expression used in the singular encompasses the expression of the plural, unless it has a clearly different meaning in the context.

In the present specification, it is to be understood that the terms such as “including,” “having,” and “comprising” are intended to indicate the existence of the features or components disclosed in the specification, and are not intended to preclude the possibility that one or more other features or components may exist or may be added. For example, unless otherwise limited, terms such as “including” or “having” may refer to either consisting of features or components described in the specification only or further including other components. Further, as used herein, the singular forms “a”, “an” and “the” (e.g., “a quantum dot”, etc.,) are intended to include the plural forms as well, unless the context clearly indicates otherwise.

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The term “group II” used herein may include a group IIA element and a group IIB element on the IUPAC periodic table, and the group II element includes, for example, magnesium (Mg), calcium (Ca), zinc (Zn), cadmium (Cd), and mercury (Hg).

The term “group III” used herein may include a group IIIA element and a group IIIB element on the IUPAC periodic table, and the group III element may include, for example, aluminum (Al), gallium (Ga), indium (In), and thallium (TI).

The term “group V” used herein may include a group VA element and a group VB element on the IUPAC periodic table, and the group V element may include, for example, nitrogen (N), phosphorus (P), arsenic (As), and antimony (Sb).

The term “group VI” used herein may include a group VIA element and a group VIB element on the IUPAC periodic table, and the group VI element may include, for example, sulfur (S), selenium (Se), and tellurium (Te).

The term “mass extinction coefficient” as used herein refers to a quantified value of a ratio of optical absorption to weight of a quantum dot with respect to light of a certain wavelength, and is calculated based on Lambert-Beer law as shown in Equation 1. In the present specification, a mass of “mass absorption coefficient” may refer to weight in grams. The weight absorption coefficient is defined as Equation 1:

Mass extinction coefficient (a)=A/c·L Equation 1

wherein, in Equation 1, A represents absorbance, c represents concentration (g/mL) of a sample solution, and L represents length (cm) of a sample solution.

The term “quantum dot” as used herein refers to a crystal of a semiconductor compound and may include any suitable material capable of emitting emission wavelengths of one or more suitable lengths according to the size of the crystal.

In the present specification, M^{In} represents number of moles of indium (In), M^{Ga} represents number of moles of gallium (Ga), and MP represents number of moles of phosphorus (P).

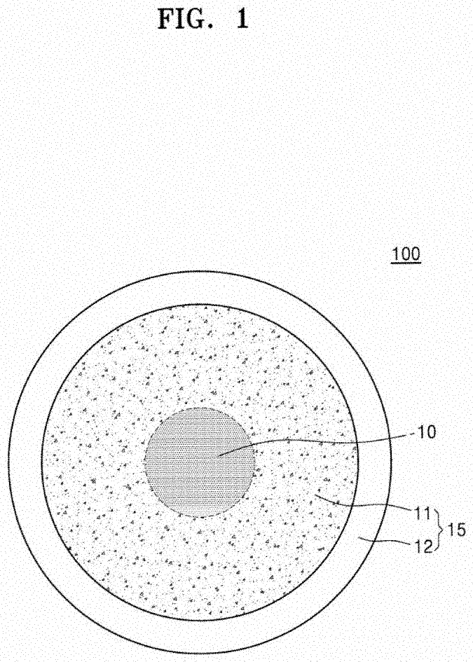

Hereinafter, a quantum dot 100 according to an embodiment will be described in connection with FIG. 1.

### Quantum dot 100

In an embodiment, the quantum dot 100 may include a core 10 and a shell 15 around (e.g., covering) at least a portion of the core 10. The core 10 may include indium (In), gallium (Ga), and phosphorus (P), and the shell 15 may include a group II-VI semiconductor compound, a group III-V semiconductor compound, a group III-VI semiconductor compound, or any combination thereof. For example, the core 10 may include InGaP.

In an embodiment, the number of moles of Ga relative to the sum of the number of moles of In and the number of moles of Ga (M^{Ga}/(M^{In}+M^{Ga})) in the core and the shell may be in a range of about 0.02 to about 0.18, about 0.03 to about 0.17, about 0.04 to about 0.16, or about 0.05 to about 0.15.

In some embodiments, the sum of the number of moles of In and the number of moles of Ga relative to the number of moles of P ((M^{In}+M^{Ga})/M^{P}) in the core and the shell may be in a range of about 1 to about 1.2.

In an embodiment, a mass extinction coefficient with respect to a wavelength of about 450 nm of the quantum dot 100 may be about 300 mL·g⁻¹·cm⁻¹ or greater, about 320 mL·g^{31 1}·cm⁻¹ or greater, or about 350 mL·g^{31 1}·cm⁻¹ or greater.

In an embodiment, a maximum emission wavelength in the PL spectrum of the quantum dot may be in a range of about 500 nm to about 540 nm, about 505 nm to about 535 nm, or about 510 nm to about 530 nm. In some embodiments, the quantum dot 100 may emit green light.

In an embodiment, a photoluminescence quantum yield (PLQY) of the quantum dot 100 may be about 80% or greater, about 85% or greater, or about 90% or greater.

In an embodiment, a retention rate of a quantum yield for a purification solvent of the quantum dot 100 to an initial quantum yield may be about 90% or greater or 95% or greater. For example, the purification solvent may be ethanol (EtOH). The “retention rate of a quantum yield for a purification solvent” refers to a degree of retention of quantum efficiency after using a purification solvent to perform purification of the quantum dot 100 three times.

In an embodiment, the shell 15 may include metal, metalloid, or nonmetal oxide, a third semiconductor compound, or a combination thereof.

Examples of the metal oxide, metalloid oxide, or nonmetal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; and one or more combinations thereof.

Examples of the third semiconductor compound may include: a group II-VI semiconductor compound; a group III-V semiconductor compound; a group III-VI semiconductor compound; a group I-III-VI semiconductor compound; a group IV-VI semiconductor compound; or one or more combinations thereof.

Examples of the group II-VI semiconductor compound may include a binary compound such as CdS, CdSe, CdTe, ZnS, ZnSe, ZnTe, ZnO, HgS, HgSe, HgTe, MgSe, or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound such as CdZnSeS, CdZnSeTe, CdZnSTe, CdHgSeS, CdHgSeTe, CdHgSTe, HgZnSeS, HgZnSeTe, or HgZnSTe; or one or more combinations thereof.

Examples of the group III-V semiconductor compound may include a binary compound such as GaN, GaP, GaAs, GaSb, AlN, AlP, AlAs, AlSb, InN, InP, InAs, or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or one or more combinations thereof. In some embodiments, the group III-V semiconductor compound may further include a group II element. Examples of the group III-V semiconductor compound further including the group II element may include InZnP, InGaZnP, InAlZnP, and/or the like.

Examples of the group III-VI semiconductor compound may include a binary compound such as GaS, GaSe, Ga₂Se₃, GaTe, InS, InSe, In₂S₃, In₂Se₃, InTe, and/or the like; a ternary compound such as InGaS₃, InGaSe₃, and/or the like; or one or more combinations thereof.

Examples of the group semiconductor compound may include a ternary compound such as AgInS, AgInS₂, CuInS, CuInS₂, CuGaO₂, AgGaO₂, AgAlO₂, or one or more combinations thereof.

Examples of the group IV-VI semiconductor compound may include a binary compound such as SnS, SnSe, SnTe, PbS, PbSe, or PbTe; a ternary compound such as SnSeS, SnSeTe, SnSTe, PbSeS, PbSeTe, PbSTe, SnPbS, SnPbSe, or SnPbTe; a quaternary compound such as SnPbSSe, SnPbSeTe, or SnPbSTe; or one or more combinations thereof.

For example, the third semiconductor compound may include ZnS, ZnSe, ZnTe, ZnO, ZnSeS, ZnTeS, GaAs, GaP, GaN, GaO, GaSb, HgS, HgSe, HgTe, InAs, InP, InS, InGaP, InSb, InZnP, InZnS, InGaP, InGaN, AlAs, AlP, AlSb, PbS, TiO, SrSe, or one or more combinations thereof.

Individual elements included in the multi-element compound, such as a binary compound, a ternary compound, and a quaternary compound, may be present in a particle thereof at a substantially uniform or substantially non-uniform concentration.

In some embodiments, the shell 15 may include ZnS, ZnSe, ZnTe, ZnO, ZnSeS, ZnTeS, ZnMg, ZnMgSe, ZnMgS, ZnMgAl, GaSe, GaTe, GaAs, GaP, GaN, GaO, GaSb, HgS, HgSe, HgTe, InAs, InP, InS, InGaP, InSb, InZnP, InZnS, InGaP, InGaN, AlAs, AlP, AlSb, PbS, TiO, SrSe, or one or more combinations thereof.

The shell 15 of the quantum dot 100 may serve as a protective layer for preventing or reducing chemical denaturation of the core 10 to maintain semiconductor characteristics and/or as a charging layer for imparting electrophoretic characteristics to the quantum dot. The shell may be a monolayer or a multilayer. An interface between a core and a shell may have a concentration gradient where a concentration of elements present in the shell decreases toward the core.

In an embodiment, the shell 15 may include at least two layers.

In an embodiment, the shell 15 may include a first shell 11 around (e.g., covering) at least a portion of the core and a second shell 12 around (e.g., covering) at least a portion of the first shell 11, and

the first shell 11 and the second shell 12 may each independently include a group II-VI semiconductor compound, a group III-V semiconductor compound, a group III-VI semiconductor compound, or one or more combinations thereof.

For example, the first shell 11 may include ZnSe or ZnSeS.

For example, the second shell 12 may include ZnS.

In some embodiments, the quantum dot 100 may have a full width of half maximum (FWHM) of a spectrum of an emission wavelength of about 65 nm or less, about 55 nm or less, or about 59 nm or less. When the FWHM of the quantum dot is within this range, color purity or color reproducibility may be improved. In some embodiments, because light emitted through the quantum dots is emitted in all directions, an optical viewing angle may be improved.

In some embodiments, the quantum dot 100 may be specifically, a spherical, pyramidal, multi-arm, or cubic nanoparticle, nanotube, nanowire, nanofiber, or nanoplate particle.

In some embodiments, the diameter of the quantum dot 100 may be, for example, in a range of about 1 nm to about 10 nm.

### Method of Manufacturing a Quantum Dot

In some embodiments,

a method of manufacturing a quantum dot may include: preparing a first composition including a precursor including indium (In), a precursor including gallium (Ga), a precursor including zinc (Zn), a fatty acid, and a solvent;

preparing a second composition including a precursor including phosphorus (P);

preparing a first mixture by mixing the first composition with the second composition;

manufacturing a core by heating the first mixture, and

manufacturing a shell covering at least a portion of the core.

In some embodiments, in the core manufactured by the manufacturing of the core may include indium (In), gallium (Ga), and phosphorus (P), and the sum of the number of moles of In and the number of moles of Ga relative to the number of moles of P ((M^{In}+M^{Ga})/M^{P}) in the core and the shell may be in a range of about 1 to about 1.5 or about 1.1 to about 1.4.

When manufacturing a core including In, Ga, and P (e.g., a core including InGaP), when a ratio of P is small in the first mixture, a bond between In and P is more advantageous kinetically than a bond between Ga and P. Thus, a bond between In and P may be predominantly formed, and Ga may be formed on a surface of a core in the form of Ga—O than Ga—P. In this embodiment, in forming a shell that covers at least a portion of the core, an exchange between the group III element and Ga may occur by a precursor containing a group III element (e.g., Zn), and Ga may be lost.

However, as described above, when a core, in which the sum of the number of moles of In and the number of moles of Ga to the number of moles of P ((M^{In}+M^{Ga})/M^{P}) is about 1 to about 1.5, is used, after forming a shell covering at least a portion of the core, it is possible to prevent or reduce loss of Ga of the core.

In some embodiments, the number of moles of P to the sum of the number of moles of In and the number of moles of Ga (M^{P}(M^{In}+M^{Ga})) in the first mixture may be in a range of about 0.7 to about 0.86.

In the manufacturing of the core, when using In, Ga, and P such that the number of moles of P (M^{P}(M^{In}+M^{Ga})) relative to the sum of the number of moles of In and the number of moles of Ga is about 0.7 to about 0.86, the sum of the number of moles of In and the number of moles of Ga relative to the number of moles of P ((M^{In}+M^{Ga})/M^{P}) may be in a range of about 1 to about 1.5, it is possible to manufacture a core in which the first exciton peak of the UV-Vis spectrum is normally formed.

In an embodiment, the half width half maximum (HWHM) of a UV-Vis spectrum of the core manufactured by the manufacturing of the core may be about 40 nm or less, about 36 nm or less, about 34 nm or less, or about 32 nm or less. Because the uniformity of the core increases as the HWHM of the UV-Vis spectrum of the core is smaller, the quantum dot formed using the core may obtain excellent or suitable photoluminescence quantum yield characteristics.

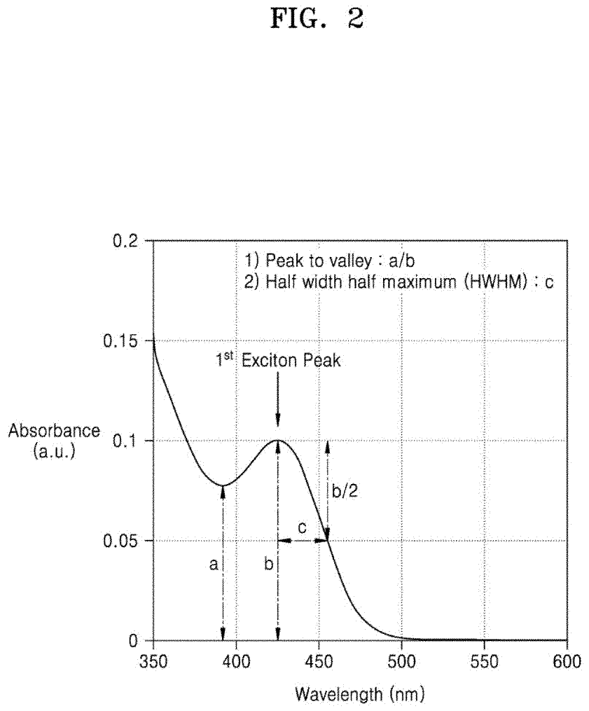

As shown in FIG. 2, the peak to valley ratio is represented by a/b in the UV-Vis spectrum of the core, and the half width half maximum (HWHM) is represented by c.

In an embodiment, a wavelength of a first exciton peak of the UV-V is spectrum of the core manufactured by the manufacturing of the core may be in a range of about 410 nm to about 440 nm. A maximum emission wavelength of the PL spectrum of the quantum dot formed using the core having the first exciton peak as described above may be in a range of about 500 nm to about 540 nm.

In an embodiment, a diameter of the core manufactured by the manufacturing of the core may be in a range of about 1.5 nm to about 2.5 nm, about 1.6 nm to about 2.4 nm, about 1.7 nm to about 2.3 nm, or about 1.8 nm to about 2.2 nm.

In an embodiment, the manufacturing of the core by heating the first mixture may include: raising the temperature from room temperature to about 250 ° C. to about 350 ° C.; and maintaining the raised temperature(s) (e.g., for a suitable period time (e.g., for each)).

In the present specification, the reaction time of the first mixture refers to the time required to raise the temperature from room temperature to a certain temperature, the time to maintain the elevated temperature, or the sum thereof.

In an embodiment, the method of manufacturing the quantum dot may include controlling a wavelength of a first exciton peak of the UV-Vis spectrum of the core manufactured by the manufacturing of the core.

As described above, to prevent or reduce loss of Ga in the core in the manufacturing of the shell, when the number of moles of P relative to the sum of the number of moles of In and the number of moles of Ga (M_{P}/(M_{In}+M_{Ga})) is increased, the wavelength of the first exciton peak of the UV-Vis spectrum of the core may be shifted to a shorter wavelength. Therefore, to obtain the maximum emission wavelength of the desired or suitable PL spectrum, for example, to obtain the maximum emission wavelength of about 500 nm to about 540 nm, the wavelength of the first exciton peak of the UV-Vis spectrum of the core may be controlled or selected.

In an embodiment, the controlling of a wavelength of a first exciton peak of a UV-Vis spectrum of the core manufactured by the manufacturing of the core may be performed by controlling at least one selected from:

i) a reaction time of the first mixture; ii) the number of moles of Zn relative to the number of moles of In (M^{Zn}/M^{In}) in the first mixture; iii) a number of carbons in the fatty acid in the first mixture; and iv) the number of moles of Ga relative to the number of moles of In (M^{Ga}/M^{In}) in the first mixture.

For example, one or two properly selected from i) to iv) may be selected for controlling.

In an embodiment, the reaction time of the first mixture may be greater than about 0 minutes and less than about 2 hours. For example, the time to maintain the raised temperature during the reaction time of the first mixture may be in a range of about 2 minutes to about 30 minutes. When the reaction time of the first mixture is long, a wavelength of a first exciton peak of the UV-Vis spectrum of the core manufactured by the manufacturing of the core may be shifted to a longer wavelength.

In an embodiment, the number of moles of Zn relative to the number of moles of In (M^{Zn}/M^{In}) in the first mixture may be greater than about 0 and about 1.5 or less. When the number of moles of Zn relative to the number of moles of In (M^{Zn}/M^{In}) is reduced, a wavelength of a first exciton peak of the UV-Vis spectrum of the core manufactured by the manufacturing of the core may be shifted to a longer wavelength.

In an embodiment, the number of carbons in the fatty acid in the first mixture may be about 6 or more and about 20 or less. When the number of carbons in the fatty acid is reduced, i.e., when the length of the fatty acid is short, a wavelength of a first exciton peak of the UV-Vis spectrum of the core manufactured by the manufacturing of the core may be shifted to a longer wavelength.

In an embodiment, the fatty acid in the first mixture may be caprylic acid, capric acid, lauric acid, myristic acid, palmitic acid, stearic acid, or arachidic acid.

In an embodiment, the number of moles of Ga relative to number of moles of In (M^{Ga}/M^{In}) in the first mixture may be in a range of about 0.05 to about 5. When the number of moles of Ga relative to the number of moles of In (M^{Ga}/M^{In}) is reduced, a wavelength of a first exciton peak of the UV-Vis spectrum of the core manufactured by the manufacturing of the core may be shifted to a longer wavelength.

Quantum dots may be synthesized by a wet chemical process, an organic metal chemical vapor deposition process, a molecular beam epitaxy process, or any similar process.

The wet chemical process is a method of growing a quantum dot particle crystal by mixing a precursor material with an organic solvent. When the crystal grows, the organic solvent may naturally serve as a dispersant coordinated on the surface of the quantum dot crystal and control the growth of the crystal. Thus, the wet chemical method may be easier to perform than the vapor deposition process such a metal organic chemical vapor deposition (MOCVD) or a molecular beam epitaxy (MBE) process. Further, the growth of quantum dot particles may be controlled or selected with a lower manufacturing cost. Optical member

The quantum dot 100 may be used in one or more suitable optical members. According to another aspect, provided is an optical member including the quantum dot.

In an embodiment, the optical member may be a color conversion member. As the color conversion member includes the quantum dot 100 having excellent or suitable light conversion efficiency as described above, the color conversion member may have excellent or suitable light conversion efficiency.

The color conversion member may include a substrate and a pattern layer formed on the substrate.

The substrate may be a substrate of the color conversion member itself or may be an area in which the color conversion member is disposed in one or more suitable devices (e.g., a display device). The substrate may be glass, silicon (Si), silicon oxide (SiOₓ) or a polymer substrate, and the polymer substrate may be polyethersulfone (PES) or polycarbonate (PC).

The pattern layer may include the quantum dot 100 in the form of a thin film. In some embodiments, the pattern layer may include the quantum dot 100 in the form of a thin film.

The color conversion member including the substrate and the pattern layer may further include a barrier rib or a black matrix formed between each pattern layer. The color conversion member may further include a color filter to further improve light conversion efficiency.

The color conversion member may include a red pattern layer capable of emitting red light, a green pattern layer capable of emitting green light, a blue pattern layer capable of emitting blue light, or any combination thereof. The red pattern layer, green pattern layer, and/or blue pattern layer may be (e.g., be each) implemented by controlling the component, composition, and/or structure of the quantum dot 100.

For example, in the color conversion members, the quantum dot 100 may absorb the first light and emit a second light different from the first light. For example, the quantum dot 100 may absorb blue light and emit visible light other than blue, e.g., visible light having a maximum emission wavelength in a range of about 495 nm to about 750 nm. Accordingly, the color conversion member including the quantum dot 100 may be designed to absorb blue light and emit wavelengths of one or more suitable color ranges.

In some embodiments, the quantum dot 100 in the color conversion member may absorb blue light to emit green light having a maximum emission wavelength in a range of about 495 nm to about 570 nm. The color conversion member including the quantum dot 100 may realize high luminance and green of high color purity.

In one or more embodiments, the optical member may be a color filter, an optical controlling member, a capping layer, a light-extraction efficiency enhancement layer, a selective light-absorption layer, or a polarizing layer.

### Electronic Apparatus

The quantum dot 100 may be used in one or more suitable electronic apparatus. According to another aspect, provided is an electronic apparatus including the quantum dot 100.

According to an embodiment, provided is an electronic apparatus 200A including: a light source 220; and a color conversion member 230 located on a pathway of light emitted from the light source 220, wherein the color conversion member 230 may include the quantum dot 100.

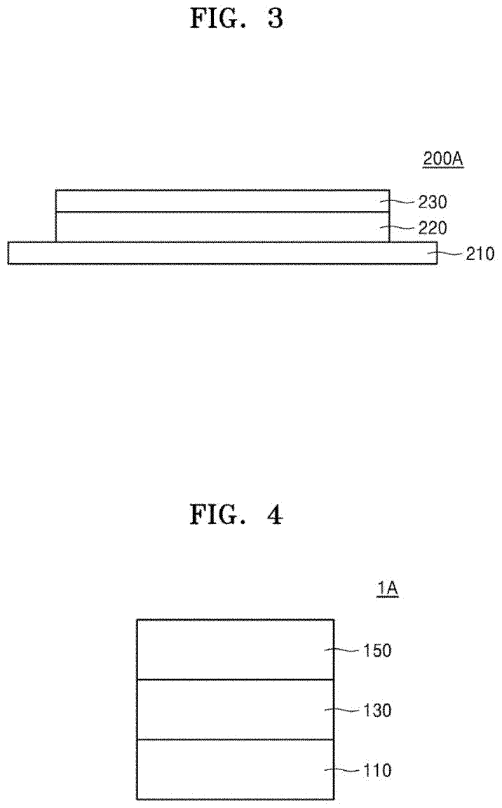

FIG. 3 is a schematic view showing a structure of an electronic apparatus 200A according to an embodiment. The electronic apparatus 200A of FIG. 3 may include a substrate 210, a light source arranged on the substrate 210, and the color conversion member 230 arranged on the light source 220.

For example, the light source 220 may be a backlight unit (BLU) for use in liquid crystal displays (LCD), a fluorescent lamp, a light-emitting device, an organic light-emitting device, or a quantum-dot light-emitting device (QLED), or one or more combinations thereof. The color conversion member 230 may be arranged in at least one traveling direction of light emitted from the light source 220.

At least part of the color conversion member 230 in the electronic apparatus 200A may include the quantum dot, and the region may absorb light emitted from the light source to thereby emit green light having a maximum emission wavelength in a range of about 500 nm to about 540 nm.

That the color conversion member 230 is arranged in at least one traveling direction of light emitted from the light source 220 may not exclude other elements from being further included between the color conversion member 230 and the light source 220.

For example, between the light source 220 and the color conversion member 230, a polarizing plate, a liquid crystal layer, a light guide plate, a diffusion plate, a prism sheet, a microlens sheet, a luminance enhancing sheet, a reflective film, a color filter, or one or more combinations thereof may be additionally arranged.

In some embodiments, a polarizing plate, a liquid crystal layer, a light guide plate, a diffusion plate, a prism sheet, a microlens sheet, a luminance enhancing sheet, a reflective film, a color filter, or one or more combinations thereof may be additionally arranged on the color conversion member 230.

The light source 220 may be a backlight unit (BLU) for use in liquid crystal displays (LCD), a fluorescent lamp, a light-emitting diode (LED), an organic light-emitting device (OLED), or a quantum-dot light-emitting device (QLED), but embodiments are not limited thereto.

The light emitted from the light source 220 as described above may be light-converted while passing through the quantum dot 100. For example, the quantum dot 100 may absorb the first light emitted from the light source 220 and emit a visible light different from the first light. For example, the quantum dot 100 may absorb blue light emitted from the light source 220 and emit a visible light having a maximum emission wavelength in a range of about 495 nm to about 750 nm. Accordingly, the quantum dot 100 or the color conversion member including the quantum dot 100 may be designed to absorb blue light emitted from the light source 220 and emit wavelengths of one or more suitable color ranges.

For example, the quantum dot 100 may absorb blue light emitted from the light source 220 and emit a green light having a maximum emission wavelength in a range of about 495 nm to about 570 nm. For example, the quantum dot 100 may absorb blue light emitted from the light source 220 and emit a red light having a maximum emission wavelength in a range of about 630 nm to about 750 nm.

Accordingly, the quantum dot 100 or the color conversion member including the quantum dot 100 may absorb blue light emitted from the light source 220 and emit green light or red light having high luminance and high colorimetric purity.

The electronic apparatus 200A illustrated in FIG. 3, which is an embodiment according to the disclosure, may have any of one or more suitable shapes, and accordingly, may further include one or more suitable structures.

In some embodiments, the electronic apparatus may include a structure including a light source, a light guide plate, a color conversion member, a first polarizing plate, a liquid crystal layer, a color filter, and a second polarizing plate that are sequentially arranged (e.g., in the stated order).

In some embodiments, the electronic apparatus may include a structure including a light source, a light guide plate, a first polarizing plate, a liquid crystal layer, a second polarizing plate, and a color conversion member that are sequentially arranged (e.g., in the stated order).

In the embodiments described above, the color filter may include a pigment or a dye. In the embodiments described above, one of the first polarizing plate and the second polarizing plate may be a vertical polarizing plate, and the other one may be a horizontal polarizing plate.

In some embodiments, the quantum dot as described in the present specification may be used as an emitter. According to another embodiment, provided is an electronic apparatus including a light-emitting device that may include: a first electrode; a second electrode facing the first electrode; and an emission layer located between the first electrode and the second electrode, wherein the light-emitting device (for example, the emission layer of the light-emitting device) may include the quantum dot. The light-emitting device may further include a hole transport region between the first electrode and the emission layer, an electron transport region between the emission layer and the second electrode, or a combination thereof.

FIG. 4 is a schematic view of a light-emitting device 1A according to an embodiment. The light-emitting device 1A may include a first electrode 110, an interlayer 130, and a second electrode 150.

The interlayer 130 may be on the first electrode 110. The interlayer 130 may include an emission layer.

The interlayer 130 may further include a hole transport region between the first electrode 110 and the emission layer and an electron transport region between the emission layer and the second electrode 150.

The interlayer 130 may further include metal-containing compounds such as organometallic compounds and one or more suitable organic materials, in addition to the quantum dot 100.

The hole transport region and the electron transport region may respectively include hole transporting materials and/or electron transporting materials suitably used in organic light-emitting devices.

The interlayer 130 may include: i) at least two emitting units sequentially stacked between the first electrode 110 and the second electrode 150; and ii) a charge generation layer located between the at least two emitting units. When the interlayer 130 includes the at least two emitting units and a charge generation layer, the light-emitting device 1A may be a tandem light-emitting device.

The emission layer may be a quantum dot single layer or a laminate structure of at least two quantum dot layers. In some embodiments, the emission layer may be a quantum dot single layer or a laminate structure of 2 to 100 quantum dot layers.

The emission layer may include the quantum dot described herein.

The emission layer may further include a quantum dot different from the quantum dot described herein.

The emission layer, in addition to the quantum dot as described herein, may further include a dispersion medium in which the quantum dot is naturally or suitably dispersed in a coordinated form. The dispersion medium may include an organic solvent, a polymer resin, or any combination thereof. Any suitable transparent medium may be used as long as the dispersion medium may not affect optical performance of the quantum dot, may not change or reflect light, and may not cause light absorption. For example, the solvent may include toluene, chloroform, ethanol, octane, or any combination thereof, and the polymer resin may include epoxy resin, silicone resin, polystyrene resin, acrylate resin, or one or more combinations thereof.

The emission layer may be formed by applying a composition for forming an emission layer including quantum dots on a hole transport region and volatilizing at least some of the solvent included in the composition for forming the emission layer.

For example, as the solvent, water, hexane, chloroform, toluene, octane, and/or the like may be used.

The coating of the composition for forming the emission layer may be performed using a spin coat method, a casting method, a micro gravure coating method, a gravure coating method, a bar coating method, a roll coating method, a wire bar coating method, a dip coating method, a spray coating method, a screen printing method, a flexographic method, an offset printing method, an ink jet printing method, and/or the like.

When the light-emitting device 1A is a full-color light-emitting device, in the emission layer 130, individual sub-pixels may include emission layers emitting different colors.

In some embodiments, the emission layer 130 may be patterned into a first color emission layer, a second color emission layer, and a third color emission layer, according to a sub-pixel. In this embodiment, at least one emission layer among the foregoing emission layers may necessarily include the quantum dot. In some embodiments, the first color emission layer may be a quantum dot emission layer including a quantum dot, and the second color emission layer and the third color emission layer may be organic emission layers each including different organic compounds. In this embodiment, the first color to the third color may be different from one another, and in some embodiments, the first color to the third color may each have different maximum emission wavelengths. The lights of the first color to the third color may be combined to be white color light.

In some embodiments, the emission layer may further include a fourth color emission layer, at least one emission layer of the first color to the fourth color emission layers may be a quantum dot emission layer including a quantum dot, and the other emission layers may be organic emission layers each including organic compounds. Such a variation may be made. In this embodiment, the first color to the fourth color may be different from one another, and in some embodiments, the first color to the fourth color may each have different maximum emission wavelengths. The lights of the first color to the fourth color may be combined to be white light.

In some embodiments, the light-emitting device 10A may have a structure in which at least two emission layers each emitting the same color or different colors may be in contact with or spaced apart from each other. At least one emission layer of the at least two emission layers may be a quantum dot emission layer including the quantum dots, and the other emission layer may be an organic emission layer including organic compounds. Such a variation may be made. For example, the light-emitting device 10A may include a first color emission layer and a second color emission layer, wherein the first color and the second color may be the same color or different colors. More specifically, both (e.g., simultaneously) the first color and the second color may be blue.

The emission layer may further include at least one selected from organic compounds and semiconductor compounds in addition to quantum dots.

In more detail, the organic compound may include a host and a dopant. The host and the dopant may include a host and a dopant suitably used in organic light-emitting devices.

In some embodiments, the semiconductor compound may be an organic perovskite and/or an inorganic perovskite.

The electronic apparatus (e.g., a light-emitting apparatus) may further include, in addition to the light-emitting device, i) a color filter, ii) a color conversion layer, or iii) a color filter and a color conversion layer. The color filter and/or the color conversion layer may be disposed on at least one traveling direction of light emitted from the light-emitting device. For example, light emitted from the light-emitting device may be blue light or white light. The light-emitting device may be understood by referring to the descriptions provided herein. In some embodiments, the color conversion layer may include quantum dots. The quantum dot may be, for example, the quantum dot described herein.

The electronic apparatus may include a first substrate. The first substrate may include a plurality of sub-pixel areas, the color filter may include a plurality of color filter areas respectively corresponding to the plurality of sub-pixel areas, and the color conversion layer may include a plurality of color conversion areas respectively corresponding to the plurality of sub-pixel areas.

A pixel-defining film may be located between the plurality of sub-pixel areas to define each sub-pixel area.

The color filter may further include a plurality of color filter areas and light-blocking patterns between the plurality of color filter areas, and the color conversion layer may further include a plurality of color conversion areas and light-blocking patterns between the plurality of color conversion areas.

The plurality of color filter areas (or a plurality of color conversion areas) may include: a first area emitting first color light; a second area emitting second color light; and/or a third area emitting third color light, and the first color light, the second color light, and/or the third color light may have different maximum emission wavelengths. In some embodiments, the first color light may be red light, the second color light may be green light, and the third color light may be blue light. In some embodiments, the plurality of color filter areas (or the plurality of color conversion areas) may each include quantum dots. In some embodiments, the first area may include red quantum dots, the second area may include green quantum dots, and the third area may not include (e.g., may exclude) a quantum dot (e.g., not include any quantum dot). The quantum dot may be understood by referring to the description of the quantum dot provided herein. The first area, the second area, and/or the third area may each further include an emitter.

In some embodiments, the light-emitting device may emit first light, the first area may absorb the first light to emit 1-1 color light, the second area may absorb the first light to emit 2-1 color light, and the third area may absorb the first light to emit 3-1 color light. In this embodiment, the 1-1 color light, the 2-1 color light, and the 3-1 color light may each have a different maximum emission wavelength. In some embodiments, the first light may be blue light, the 1-1 color light may be red light, the 2-1 color light may be green light, and the 3-1 light may be blue light.

The electronic apparatus may further include a thin-film transistor, in addition to the light-emitting device. The thin-film transistor may include a source electrode, a drain electrode, and an active layer, wherein one of the source electrode or the drain electrode may be electrically connected to one of the first electrode or the second electrode of the light-emitting device.

The thin-film transistor may further include a gate electrode, a gate insulating film, and/or the like.

The active layer may include a crystalline silicon, an amorphous silicon, an organic semiconductor, and an oxide semiconductor.

The electronic apparatus may further include an encapsulation unit for sealing the light-emitting device. The encapsulation unit may be located between the color filter and/or the color conversion layer and the light-emitting device. The encapsulation unit may allow light to pass to the outside from the light-emitting device and prevent or reduce the air and moisture to permeate to the light-emitting device at the same time. The encapsulation unit may be a sealing substrate including transparent glass or a plastic substrate. The encapsulation unit may be a thin-film encapsulating layer including at least one of an organic layer and/or an inorganic layer.

When the encapsulation unit is a thin-film encapsulating layer, the electronic apparatus may be flexible.

In addition to the color filter and/or the color conversion layer, one or more suitable functional layers may be disposed on the encapsulation unit depending on the use of an electronic apparatus. Examples of the functional layer may include a touch screen layer, a polarizing layer, and/or the like. The touch screen layer may be a resistive touch screen layer, a capacitive touch screen layer, or an infrared beam touch screen layer. The authentication apparatus may be, for example, a biometric authentication apparatus that identifies an individual according to biometric information (e.g., a fingertip, a pupil, and/or the like).

The authentication apparatus may further include a biometric information collecting unit, in addition to the light-emitting device described above.

The electronic apparatus may be applicable to one or more suitable displays, an optical source, lighting, a personal computer (e.g., a mobile personal computer), a cellphone, a digital camera, an electronic note, an electronic dictionary, an electronic game console, a medical device (e.g., an electronic thermometer, a blood pressure meter, a glucometer, a pulse measuring device, a pulse wave measuring device, an electrocardiograph recorder, an ultrasonic diagnosis device, or an endoscope display device), a fish finder, one or more suitable measurement devices, gauges (e.g., gauges of an automobile, an airplane, or a ship), and/or a projector.

Hereinafter, the quantum dot 100 according to one or more embodiments will be described in more detail with reference to Examples.

### EXAMPLES

### Example 1-1.

1. Manufacture of InGaP core

To synthesize an InGaP core, about 10.5 mmol of indium acetate, about 10.5 mmol of zinc acetate, about 8.4 mmol of gallium acetylacetonate (at a molar ratio of In:Zn:Ga=about 1:1:0.8), about 77.7 mmol of palmitic acid, and about 35 mL of a solvent of 1-octadecene (1-ODE) were added to a flask, followed by degassing at a temperature of about 120° C. and purging with nitrogen (the total volume of the precursor solution was about 55 mL).

In a separate reaction vessel, about 10 mL of the precursor solution was injected to about 5 mL of degassed 1-ODE (at an injection temperature of about 50° C.), and about 3.9 mL of a solution of tris(trimethylsilyl)phosphine and trioctylphospine at a ratio of about 1:4 was injected thereto. Then, the temperature was raised to about 300° C. in a microwave synthesizer (3-neck flask may also be utilized. It is not limited to microwaves), and then, the reaction was maintained for about 2 minutes. Then, the mixture was cooled to room temperature to complete the reaction. Then, purification process was performed using acetone, and the purified InGaP core was redispersed in toluene.

### 2. Manufacture of Shell

About 30 mmol of zinc oleate, about 20 mmol of trioctylphosphine selenide, a trioctylamine solvent, and about 10 mmol of oleylamine and about 1.0 mmol to about 10 mmol of ZnCl2 were added as additives to InGaP core dispersed in toluene, followed by reaction for about 1 hour at a temperature of about 320° C. or higher, thereby forming a zinc selenide (ZnSe) shell.

Then, about 30 mmol of zinc oleate, about 30 mmol of trioctylphosphine sulfide, and about 5 mmol of oleylamine and about 1.0 mmol to about 10 mmol of ZnCl₂ were added as additives thereto, followed by reaction for about 1 hour at a temperature of about 320° C. higher, thereby forming a zinc sulfide (ZnS) shell. Thus, a quantum dot having a structure of InGaP/ZnSe/ZnS was synthesized. Then, purification was performed by using ethanol, and the purified quantum dot was redispersed in toluene.

### Examples 1-2 and 1-3

A core and a quantum dot was manufactured in substantially the same manner as in Example 1-1, except that the reaction time was adjusted as shown in Table 1.

### Comparative Examples 1-1 to 1-4

Cores and quantum dots were manufactured in substantially the same manner as in Example 1-1, except that the number of moles of P relative to the sum of the number of moles of In and the number of moles of Ga (M^{P}(M^{In}+M^{Ga})) were adjusted in manufacture of an InGaP core as shown in Table 1.

### Evaluation Example 1 Evaluation of M^{P}/(M^{In}+M^{Ga}) and Characteristics of Core and Shell Over Reaction Time

The first exciton peak, peak to valley ratio, half width half maximum (HWHM), and ICP composition ratio of each of the InGaP cores manufactured in Examples 1-1 to 1-3 and Comparative Examples 1-1 to 1-4 and the ICP composition ratio of each of the quantum dots manufactured in Example 1-1 and Comparative Examples 1-1 to 1-4 were measured. The results thereof are shown in Table 1. The ICP composition ratio was measured by using an inductively coupled plasma-mass spectrometer.

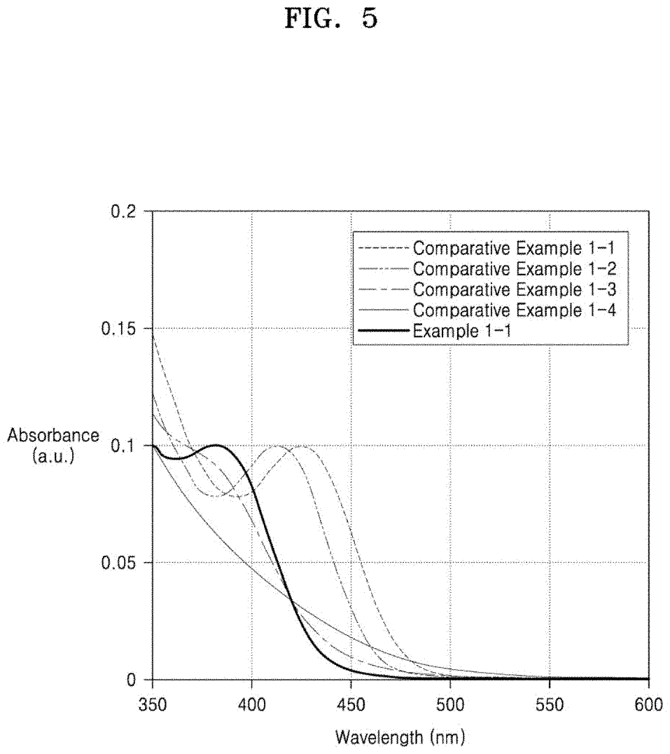

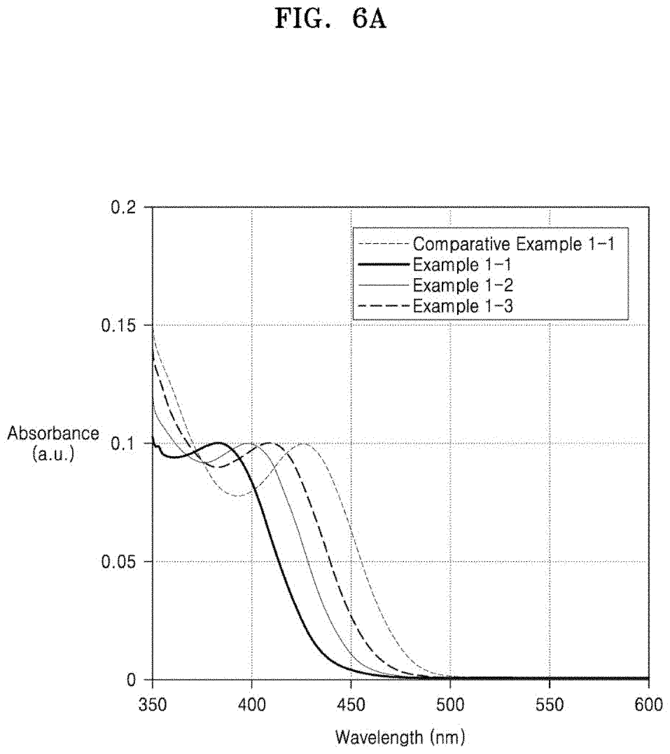

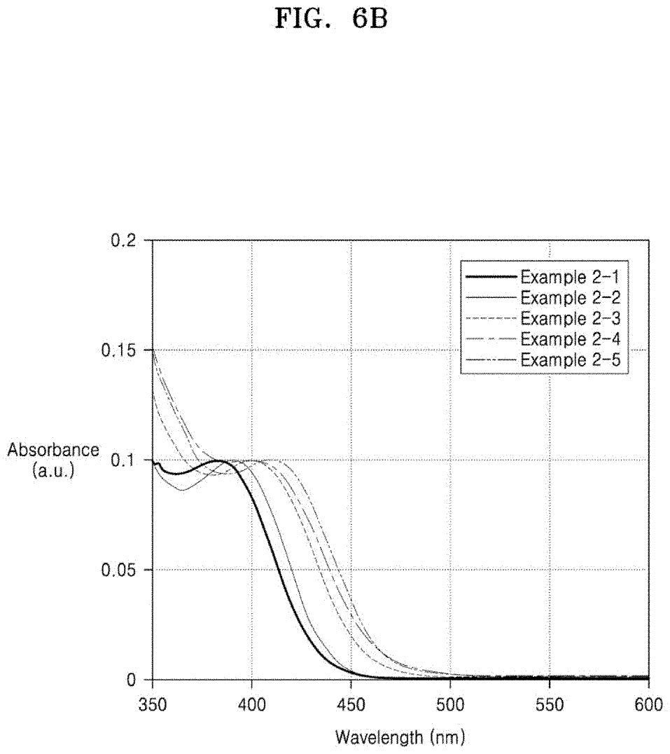

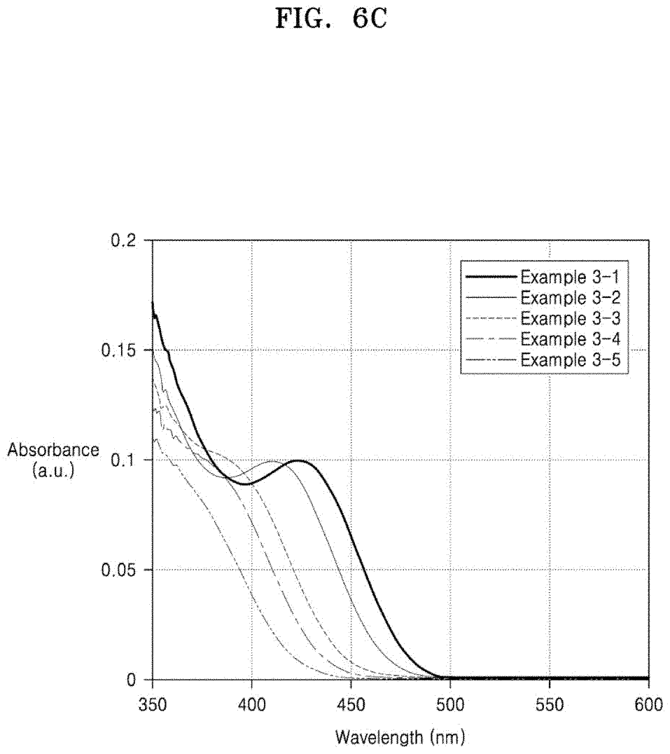

In some embodiments, the UV-Vis spectrum of each of the InGaP cores of Examples 1-1 and Comparative Examples 1-1 to 1-4 is shown in FIG. 5. The UV-Vis spectrum of each of the InGaP core of Examples 1-1 to 1-3 and Comparative Example 1-1 is shown in FIG. 6A.

TABLE 1

| | | | | | | | | | ICP | |
|---|---|---|---|---|---|---|---|---|---|---|
| | Core synthesis | | UV-vis optical | | | | | | composition | |
| | condition | | characteristics of core | | | ICP composition | | | ratio after | |
| | M^{P}/ | Reaction | 1^{st} | Peak | | ratio of core | | Core | shell coating | |
| | (M^{In} + | time | exciton | to | | Ga/ | (In + Ga)/ | diameter | Ga/ | (In + Ga)/ |
| | M^{Ga}) | (min) | Peak | valley | HWHM | (Ga + In) | P | (nm) | (Ga + In) | P |
| Comparative | 0.54 | 2 | 425 | 0.78 | 30 | 0.38 | 1.92 | 2.18 | 0 | 1.2 |
| Example | | | | | | | | | | |
| 1-1 | | | | | | | | | | |
| Comparative | 0.66 | 2 | 412 | 0.78 | 30 | 0.37 | 1.67 | 2.09 | 0.02 | 1.1 |
| Example | | | | | | | | | | |
| 1-2 | | | | | | | | | | |
| Example | 0.77 | 2 | 382 | 0.94 | 31 | 0.39 | 1.40 | 1.95 | 0.21 | 1.1 |
| 1-1 | | | | | | | | | | |
| Example | | 10 | 397 | 0.92 | 31 | 0.39 | 1.39 | 2.00 | — | — |
| 1-2 | | | | | | | | | | |
| Example | | 20 | 407 | 0.90 | 32 | 0.38 | 1.37 | 2.14 | — | — |
| 1-3 | | | | | | | | | | |
| Comparative | 0.86 | 2 | — | — | — | 0.39 | 1.30 | 2.02 | 0.25 | 1.1 |
| Example | | | | | | | | | | |
| 1-3 | | | | | | | | | | |
| Comparative | 1.00 | 12 | — | — | — | 0.40 | 1.16 | 5.06 | — | — |
| Example | | | | | | | | | | |
| 1-4 | | | | | | | | | | |

Referring to the results of Table 1 and FIG. 5, the first exciton peak and HWHM characteristics of the InGaP core of Example 1-1 were maintained, and after forming the shell, the Ga content (e.g., amount) in the quantum dot was maintained to a certain level.

In some embodiments, referring to the results of Table 1 and FIG. 6A, as the reaction time in the manufacture of the core increases, the first exciton peak of the InGaP core was shifted to a longer wavelength.

### Examples 2-1 to 2-5

To synthesize InGaP cores, the In, Ga, and Zn precursors were prepared by equivalent weight as shown in Table 2. Fatty acid corresponding to the cation equivalent and 35 mL of 1-octadecene, a solvent, were placed in a flask, degassed at a temperature of about 120° C., and then switched to nitrogen atmosphere.

In a separate reaction vessel, about 10 mL of the precursor solution was injected to about 5 mL of degassed 1-octadecene (injection temperature of about 50° C.). To the solution, about 3.9 mL of a solution in which tris(trimethylsilyl)phosphine and trioctylphospine were mixed at a ratio of about 1:4 was added such that M^{P}/(M^{In}+M^{Ga}) of the core was about 0.77. Then, the temperature was raised to about 300° C. in a microwave synthesizer (3-neck flask may also be used. It is not limited to microwaves), and then, the reaction was maintained for about 2 minutes. Then, the reaction was complete by cooling to room temperature, and after purification with acetone, the resulting solution was dispersed in toluene.

TABLE 2

| | Composition | | | | | |
|---|---|---|---|---|---|---|
| | of | | | | Fatty acid (mmol) | |
| | precursor, | In | Zn | Ga acetyl | Palmitic | Lauric |
| | fatty acid | acetate | acetate | acetonate | acid | acid |
| | type or kind | (mmol) | (mmol) | (mmol) | (PA) | (LA) |
| Example | M^{Zn}/M^{In} = | 10.5 | 10.5 | 8.4 | 77.7 | 0 |
| 2-1 | 1.0, PA | | | | | |
| Example | M^{Zn}/M^{In} = | 10.5 | 10.5 | 8.4 | 0 | 77.7 |
| 2-2 | 1.0, LA | | | | | |
| Example | M^{Zn}/M^{In} = | 10.5 | 5.25 | 8.4 | 67.2 | 0 |
| 2-3 | 0.5, PA | | | | | |
| Example | M^{Zn}/M^{In} = | 10.5 | 2.63 | 8.4 | 62.0 | 0 |
| 2-4 | 0.25, PA | | | | | |
| Example | M^{Zn}/M^{In} = | 10.5 | 2.63 | 8.4 | 0 | 62.0 |
| 2-5 | 1.0, LA | | | | | |

Evaluation Example 2 Evaluation of M^{Zn}/M^{In} and characteristics of cores according to fatty acid

FIG. 6B shows a graph illustrating UV-Vis spectra of InGaP cores according to Examples 2-1 to 2-5. As shown in FIG. 6B, when the number of moles of Zn relative to the number of moles of In (M^{Zn}/M^{In}) or the number of carbons in the fatty acid is reduced (i.e., the fatty acid is reduced in length), a wavelength of a first exciton peak of the UV-Vis spectrum of the core was found to be shifted to a longer wavelength.

### Examples 3-1 to 3-5

To synthesize InGaP cores, the In, Ga, and Zn precursors were prepared by equivalent weight as shown in Table 3. Lauric acid corresponding to the cation equivalent and about 35 mL of 1-octadecene, a solvent, were placed in a flask, degassed at a temperature of about 120° C., and then switched to nitrogen atmosphere.

In a separate reaction vessel, some of the precursor solution was injected to about 5 mL of degassed 1-octadecene (injection temperature of about 50° C.). To the solution, about 3.9 mL of a solution in which tris(trimethylsilyl)phosphine and trioctylphospine were mixed at a ratio of about 1:4 was added such that M^{P}/(M^{In}+M^{Ga}) of the core was about 0.77. Then, the temperature was raised to about 300° C. in a microwave synthesizer (3-neck flask may also be used. It is not limited to microwaves), and then, the reaction was maintained for 2 minutes. Then, the reaction was complete by cooling to room temperature, and after purification with acetone, the resulting solution was dispersed in toluene.

TABLE 3

| | | In | Zn | Ga | Lauric |
|---|---|---|---|---|---|
| | Precursor | acetate | acetate | acetate | acid |
| | composition | (mmol) | (mmol) | (mmol) | (mmol) |
| Example 3-1 | M^{Ga}/M^{In} = 0.8 | 10.5 | 2.63 | 8.4 | 62.0 |
| Example 3-2 | M^{Ga}/M^{In} = 1.0 | 9.45 | 2.63 | 9.45 | 62.0 |
| Example 3-3 | M^{Ga}/M^{In} = 1.5 | 7.56 | 2.63 | 11.34 | 62.0 |
| Example 3-4 | M^{Ga}/M^{In} = 2.0 | 6.3 | 2.63 | 12.6 | 62.0 |
| Example 3-5 | M^{Ga}/M^{In} = 3.0 | 4.73 | 2.63 | 14.17 | 62.0 |

### Evaluation Example 3-1. UV-Vis Spectrum of Cores According to M^{Ga}/M^{In}

FIG. 6C shows a graph illustrating UV-Vis spectra of InGaP cores according to Examples 3-1 to 3-5. As shown in FIG. 6C, when the number of moles of Ga relative to the number of moles of In (M^{Ga}/M^{In}) is reduced, a wavelength of a first exciton peak of the UV-Vis spectrum of the core was found to be shifted to a longer wavelength.

### Evaluation Example 3-2. ICP Composition Ratio of Cores According to M^{Ga}/M^{In}

The ICP composition ratio of each of the InGaP cores of Examples 3-1 to 3-5 are shown in Table 4.

TABLE 4

| | |
|---|---|
| Ga/In | ICP composition ratio |

| Injection ratio | Ga/(Ga + In) | (In + Ga)/P |
|---|---|---|
| 0.8 | 0.28 | 1.30 |
| 1.0 | 0.30 | 1.32 |
| 1.5 | 0.47 | 1.33 |
| 2.0 | 0.51 | 1.32 |
| 3.0 | 0.61 | 1.33 |

### Examples 4-1 to 4-9

9 types (kinds) of quantum dots were synthesized such that the half width at half maximum (HWHM) values of the cores were different from each other. Here, the synthesized 9 kinds of quantum dots were named Examples 4-1 to 4-9 in order from the quantum dot with the smallest HWHM value of the core.

Quantum dots of Examples 4-1 to 4-9 were synthesized in substantially the same manner as in Manufacture of shell in Example 1-1, except that cores each included InGaP, and the shells of the quantum dots of Examples 4-1 to 4-9 each had a different type or kind of core.

Evaluation Example 4 Quantum yield of core-shell quantum dots according to HWHM of cores

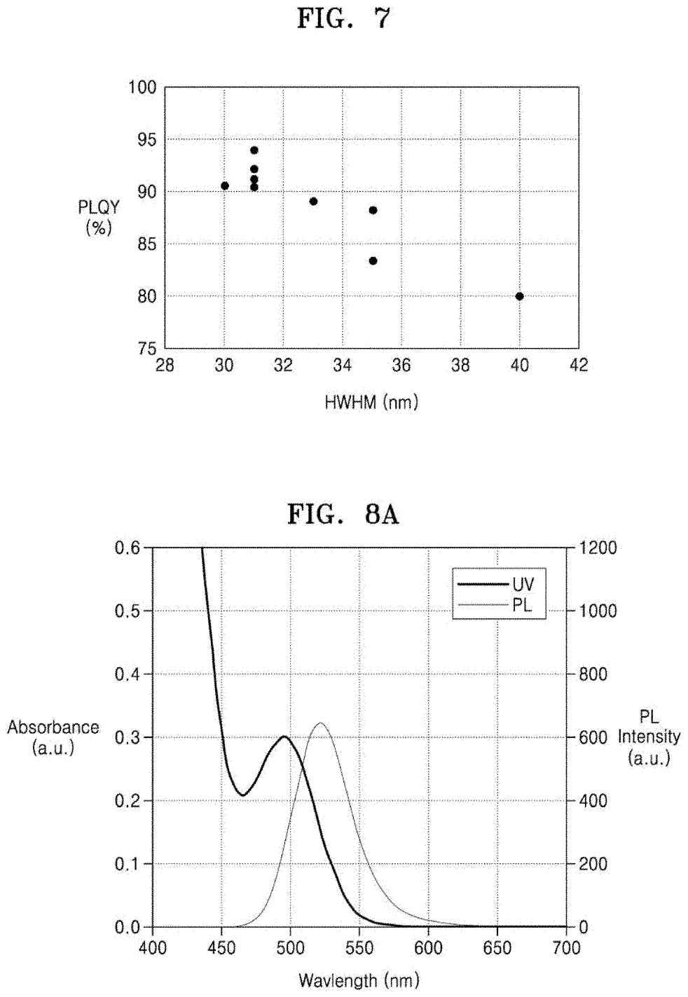

The HWHM of each of the cores of Examples 4-1 to 4-9 was measured, and the quantum yield (PLQY) of each of the quantum dots of Examples 4-1 to 4-9 was measured. The results thereof are shown in FIG. 7.

As shown in FIG. 7, when the HWHM of the core is decreased, the quantum yield of the quantum dot increased.

### Examples 5-1 and 5-2 and Comparative Examples 5-1 to 5-3

Quantum dots including the cores and shells as described in Table 5 were synthesized. Quantum dots of Examples 5-1 and 5-2 and Comparative Examples 5-1 to 5-3 were synthesized in substantially the same manner as in Manufacture of shell in Example 1-1, except that the shells of the quantum dots of Examples 5-1 and 5-2 and Comparative Examples 5-1 to 5-3 each had a different type or kind of core.

### Evaluation Example 5

The ICP composition ratio, weight absorption coefficient, and quantum yield (PLQY) of the cores and the quantum dots of Examples 5-1 and 5-2 and Comparative Examples 5-1 to 5-3 were measured. The results thereof are shown in Table 5. In Table 5, the weight absorption coefficient was measured with respect to a wavelength of about 450 nm. The unit was mL·g⁻¹·cm⁻¹.

TABLE 5

| | | ICP composition | | ICP composition ratio | | Weight | |
|---|---|---|---|---|---|---|---|
| | | ratio of core | | after shell coating | | absorption | |
| | | M^{Ga}/ | (M^{In} + | M^{Ga}/ | (M^{In} + | coefficient | PLQY |
| | Core | (M^{In} + M^{Ga}) | M^{Ga})/M^{P} | (M^{In} + M^{Ga}) | M^{Ga})/M^{P} | (@ 450 nm) | (%) |
| Comparative | InP | 0 | 1.1 | 0 | 1.1 | 230 | 97 |
| Example 5-1 | | | | | | | |
| Comparative | InGaP | 0.38 | 1.92 | 0 | 1.2 | 233 | 95 |
| Example 5-2 | | | | | | | |
| Example 5-1 | InGaP | 0.20 | 1.33 | 0.06 | 1.1 | 351 | 93 |
| Example 5-2 | InGaP | 0.26 | 1.35 | 0.13 | 1.1 | 396 | 90 |
| Comparative | InGaP | 0.40 | 1.30 | 0.20 | 1.1 | 420 | 73 |
| Example 5-3 | | | | | | | |

Referring to the Table 3, it was found that the quantum dots according to Examples 5-1 and 5-2 each show high absorbance and high quantum yield for a wavelength of about 450 nm.

### Example 6

Quantum dots including the core and the shell were synthesized such that M^{Ga}/(M^{In}+M^{Ga}) of the quantum dot was about 0.13. A quantum dot of Example 6 was synthesized in substantially the same manner as in Manufacture of shell in Example 1-1, except that the shell of the quantum dot of Example 6 had a different type or kind of core.

### Evaluation Example 6-1

The ICP composition ratio, quantum yield, weight absorption coefficient, retention rate of the quantum yield (QY) with respect to EtOH of the quantum dot of Example 6 was measured. The results thereof are shown in Table 6.

The weight absorption coefficient is a predicted value for the blue light absorption efficiency. The weight absorption coefficient may be calculated by measuring the about 450 nm wavelength optical density of the QD solution with suitable concentration in an about 1 cm path length cuvette using UV-Vis equipment, and dividing it by the concentration (g/mL) of the QD solution. In Table 6, the unit for the weight absorption coefficient was mL·g⁻¹·cm⁻¹.

After confirming the initial quantum yield value of the quantum dot, followed by three consecutive purifications with ethanol (intermediate redispersion in toluene), the retention rate of the quantum yield with respect to EtOH was measured, and was expressed based on the initial value of 100%.

TABLE 6

| | | | | Retention |
|---|---|---|---|---|
| | ICP | | Weight | rate of QY |
| | composition | | absorption | with respect |
| | ratio | PLQY | coefficient | to EtOH |
| | (M^{Ga}/(M^{In} + M^{Ga})) | (%) | (@ 450 nm) | (%) |
| Example 6 | 0.13 | 90 | 396 | 95 |

### Evaluation Example 6-2

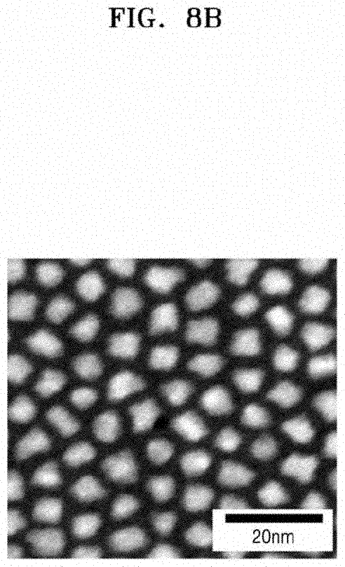

The UV-Vis spectrum and PL spectrum of the quantum dot of Example 6 were measured and shown in FIG. 8A, and the HAADF TEM image of the quantum dot of Example 6 was taken and shown in FIG. 8B.

As should now be apparent from the foregoing description, as the quantum dot has high absorbance and quantum yield, a high-quality optical member and electronic apparatus may be provided by using the quantum dot. The method of manufacturing the quantum dot may prepare a quantum dot with high absorbance and quantum yield by preventing or reducing loss of gallium (Ga) of the core during the shell formation process.

In the present disclosure, when particles are spherical, “diameter” indicates an average particle diameter, and when the particles are non-spherical, the “diameter” indicates a major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The electronic apparatus and/or any other relevant device or devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A quantum dot comprising:
a core; and
a shell around at least a portion of the core,
wherein the core comprises indium (In), gallium (Ga), and phosphorus (P),
the shell comprises a group II-VI semiconductor compound, a group III-V semiconductor compound, a group III-VI semiconductor compound, or any combination thereof,
in the core and the shell, a number of moles of Ga relative to a sum of a number of moles of In and a number of moles of Ga (M^{Ga}/(M^{In}+M^{Ga})) is in a range of about 0.02 to about 0.18, and
in the core and the shell, a sum of a number of moles of In and a number of moles of Ga relative to a number of moles of P ((M^{In}+M^{Ga})/M^{P}) is in a range of about 1 to about 1.2.

2. The quantum dot of claim 1, wherein a weight absorption coefficient with respect to a wavelength of about 450 nanometers (nm) is about 300 mL·g^{31 1}·cm⁻¹ or greater.

3. The quantum dot of claim 1, wherein a maximum emission wavelength of a photoluminescence (PL) spectrum of the quantum dot is in a range of about 500 nm to about 540 nm.

4. The quantum dot of claim 1, wherein a photoluminescence quantum yield of the quantum dot is about 80 percent (%) or higher.

5. The quantum dot of claim 1, wherein the shell comprises ZnS, ZnSe, ZnTe, ZnO, ZnSeS, ZnTeS, ZnMg, ZnMgSe, ZnMgS, ZnMgAl, GaSe, GaTe, GaAs, GaP, GaN, GaO, GaSb, HgS, HgSe, HgTe, InAs, InP, InS, InGaP, InSb, InZnP, InZnS, InGaP, InGaN, AlAs, AlP, AlSb, PbS, TiO, SrSe, or one or more combinations thereof.

6. The quantum dot of claim 1, wherein the shell comprises at least two layers.

7. A method of manufacturing a quantum dot, the method comprising:
preparing a first composition comprising a precursor comprising indium (In), a precursor comprising gallium (Ga), a precursor comprising zinc (Zn), a fatty acid, and a solvent;
preparing a second composition comprising a precursor comprising phosphorus (P);
preparing a first mixture by mixing the first composition with the second composition;
manufacturing a core by heating the first mixture; and
manufacturing a shell around at least a portion of the core,
wherein the core manufactured by the manufacturing of the core comprises indium (In), gallium (Ga), and phosphorus (P),
in the core, a sum of a number of moles of In and a number of moles of Ga relative to a number of moles of P ((M^{In}+M^{Ga})/M^{P}) is in a range of about 1 to about 1.5.

8. The method of claim 7, wherein, in the first mixture, a number of moles of P relative to a sum of a number of moles of In and a number of moles of Ga (M^{P}(M^{In}+M^{Ga})) is in a range of about 0.7 to about 0.86.

9. The method of claim 7, wherein a half width half maximum (HWHM) of a UV-Vis spectrum of the core is about 40 nm or less.

10. The method of claim 7, wherein a wavelength of a first exciton peak of a UV-Vis spectrum of the core is in a range of about 410 nm to about 440 nm.

11. The method of claim 7, wherein a diameter of the core manufactured by the manufacturing of the core is in a range of about 1.5 nm to about 2.5 nm.

12. The method of claim 7, comprising controlling a wavelength of a first exciton peak of a ultraviolet-visible (UV-Vis) spectrum of the core.

13. The method of claim 12, wherein the controlling of a wavelength of a first exciton peak of a UV-Vis spectrum of the core is performed by controlling at least one of: i) a reaction time of the first mixture; ii) a number of moles of Zn relative to a number of moles of In (M^{Zn}/M^{In}) in the first mixture; iii) a number of carbons in the fatty acid in the first mixture; and iv) a number of moles of Ga relative to a number of moles of In (M^{Ga}/M^{In}) in the first mixture.

14. The method of claim 13, wherein the reaction time of the first mixture is greater than about 0 minutes and less than or equal to about 2 hours.

15. The method of claim 13, wherein, in the first mixture, the number of moles of Zn relative to the number of moles of In (M^{Zn}/M^{In}) is greater than about 0 and less than or equal to about 1.5.

16. The method of claim 13, wherein, in the first mixture, the number of moles of Ga relative to the number of moles of In (M^{Ga}/M^{In}) is in a range of about 0.05 to about 5.

17. An optical member comprising the quantum dot of claim 1.

18. An electronic apparatus comprising the quantum dot of claim 1.

19. The electronic apparatus of claim 18, comprising:
a light source configured to emit light; and
a color conversion member arranged on a pathway of the light emitted from the light source,
wherein the quantum dot is comprised in the color conversion member.

20. The electronic apparatus of claim 18, comprising:
a light-emitting device comprising:
a first electrode;
a second electrode facing the first electrode; and
an emission layer between the first electrode and the second electrode, wherein the quantum dot is comprised in the light-emitting device.
